(19) United States
(12) Patent Application Publication
(10) Pub. No.: US 2007/0173049 A1
(43) Pub. Date: Jul. 26, 2007

(54) Capacitor and method for fabricating the same

(75) Inventors: Jeong-Lim Kim, Seoul (KR); Kwan-Young Youn, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/634,151

(22) Filed: Dec. 6, 2006

(30) Foreign Application Priority Data
Jan. 20, 2006 (KR) 10-2006-0006239

(51) Int. Cl. H01L 21/44

(52) U.S. Cl. 438/597

(57) ABSTRACT

There is provided a capacitor and a method for fabricating the same. The method may include forming an interlayer insulation layer on a semiconductor substrate, patterning the interlayer insulation layer to form a contact hole exposing a region of the semiconductor substrate and forming a contact plug by filling the contact hole, wherein a top of the contact plug may have a height identical to that of the interlayer insulation layer. The method may further include forming a recess on the interlayer insulation layer, the recess exposing a portion of the contact plug, forming a bottom electrode on an inner profile of the recess including sides of the contact plug and depositing a dielectric layer and a top electrode on a profile of the semiconductor substrate including the bottom electrode to form a capacitor.

### PRIORITY STATEMENT

This application claims priority under 35 U.S.C. §119 to Korean Patent Application No. 10-2006-0018886, filed on Jan. 20, 2006, in the Korean Intellectual Property Office (KIPO), the entire contents of which are incorporated herein by reference.

### BACKGROUND

1. Field

Example embodiments relate to a capacitor and method for fabricating the same.

2. Description of the Related Art

Because semiconductor devices have become highly integrated, a region that unit devices occupy on a semiconductor wafer may be reduced and a region that a capacitor occupies may also be reduced. The capacitor may be used in memory devices (e.g., Dynamic Random Access Memory (DRAM) and/or Static Ram (SRAM)). The capacitor may include respectively opposite conductive layers and a dielectric layer between the conductive layers. The capacitor may require a predetermined or given level of capacitance.

There have been many efforts to improve the capacitance of the capacitor. The surface region of respectively opposite conductive layers may be increased to improve the capacitance of a capacitor. A three-dimensional capacitor may be used to increase the surface region of the capacitor. A representative three-dimensional capacitor may be a stack capacitor. Examples of the stack capacitor may be a double-stacked capacitor, a fin-stacked capacitor, a cylindrical capacitor and/or a box-structure capacitor. The inner surface and the outer surface of the cylindrical capacitor may be effective regions of the capacitor. The cylindrical capacitor may be in one of several forms.

FIG. 1 is a diagram of an embedded DRAM with a capacitor under bit line structure according to a conventional art. Referring to FIG. 1, a device isolation layer 12 may be formed on a semiconductor substrate 10 using a conventional device isolation process. A gate oxide layer 14, a gate electrode 16, and impurity regions (source and drain regions 18s and 18d) may be formed on the semiconductor substrate 10 by using a conventional Metal-Oxide Semiconductor (MOS) transistor manufacturing process.

A first interlayer insulation layer 20 may be formed on the semiconductor substrate 10 having the MOS transistor. The first interlayer insulation layer 20 may include contact holes 21 that may be formed to expose the impurity regions 18s and 18d. Contact plugs 22 may be formed to fill the contact holes 21. An etch stop layer 24 and a second interlayer insulation layer 26 having a recess may be formed on the first interlayer insulation layer 20 having the contact plugs 22. The recess may expose a predetermined or given region of the first interlayer insulation layer 20 having the contact plugs 22 connected to the drain regions 18d.

A bottom electrode 30 may be formed on an inner profile of the recess. According to a profile of the second interlayer insulation layer 26 having the bottom electrode 30, a dielectric layer 35 and a top electrode 40 may be formed by depositing and patterning a dielectric material and a top conductive layer. A third interlayer insulation layer 50 may be formed on the second interlayer insulation layer 26 having the top electrode 40. The third interlayer insulation layer 50 may include a bit-line contact hole 51b exposing the contact plug 22 connected to the source region 18s, and a metal-line contact hole 51m exposing a predetermined or given region of the top electrode 40. A bit-line contact plug 52b and a metal-line contact plug 52m may be formed to fill the bit-line contact hole 51b and the metal-line contact hole 51m, respectively.

When manufacturing a capacitor of the semiconductor device with the above Capacitor Under Bit-line (CUB), a design rule may be reduced due to the relatively high integration of the semiconductor device. Therefore, it may be difficult to obtain effective capacitance of the capacitor. Due to CUB structure characteristics, when the height of the capacitor is increased to obtain more capacitance, there may be limitations in forming contact holes for a bit-line contact during an etching process and in forming a contact plug.

### SUMMARY

Example embodiments provide a capacitor improving capacitance and a method for fabricating the same.

Example embodiments provide a method for fabricating a capacitor. The method may include forming an interlayer insulation layer on a semiconductor substrate, patterning the interlayer insulation layer to form a contact hole exposing a region of the semiconductor substrate, forming a contact plug by filling the contact hole, wherein a top of the contact plug may havea height identical to that of the interlayer insulation layer.

The method may further include forming a recess on the interlayer insulation layer, the recess exposing a portion of contact plug, forming a bottom electrode on an inner profile of the recess including sides of the contact plug and depositing a dielectric layer and a top electrode on a profile of the semiconductor substrate including the bottom electrode to form a capacitor.

In example embodiments, the interlayer insulation layer may be formed of a silicon oxide. An etch stop layer inserted in a middle of the interlayer insulation layer, and the interlayer insulation layer formed on a top of the etch stop layer may havea thickness that becomes a depth of the recess. The etch stop layer may be formed of one of a silicon oxide nitride layer and a silicon nitride layer. In further example embodiments, the contact plug may be formed of tungsten. The forming of the recess may be performed using an anisotropic dry etching process.

In other example embodiments, the forming of the bottom electrode may include depositing a bottom conductive layer on a profile of the recess, forming a sacrificial insulation layer that covers the semiconductor substrate including the bottom conductive layer and the recess, etching an entire surface of the sacrificial insulation layer and the bottom conductive layer to expose a surface of the interlayer insulation layer and removing the sacrificial insulation layer remaining in the recess by an ashing process.

In other example embodiments, the bottom conductive layer may be formed of a titanium nitride. The sacrificial insulation layer may be formed of a photoresist. The etching of the entire surface of the sacrificial insulation layer and the bottom conductive layer may be performed by using a CMP process. In other example embodiments, the dielectric layer may be formed of aluminum oxide and hafnium oxide. The top electrode may be formed of a titanium nitride.

According to example embodiments, a capacitor may include a gate electrode formed on a semiconductor substrate, an interlayer insulating layer covering an entire surface of the semiconductor substrate having the gate electrode, and including a recess, a contact plug connected to a region of the semiconductor substrate, and protruding from a center of the recess. A top of the contact plug may have a height identical to that of the interlayer insulation layer.

A bottom electrode may be formed on an inner profile of the recess having sides of the contact plug and a dielectric layer and a top electrode may be deposited on a profile of the semiconductor substrate having the bottom electrode. In some example embodiments, the interlayer insulation layer may be a silicon oxide layer. The capacitor further may include an etch stop layer inserted in a middle of the interlayer insulation layer. The etch stop layer may be one of a silicon oxide nitride layer and a silicon nitride layer. The contact plug may be formed of tungsten. The bottom electrode may be formed of a titanium nitride layer. The dielectric layer may be a double layer including aluminum oxide and hafnium oxide. The top electrode may be formed of a titanium nitride layer.

### BRIEF DESCRIPTION OF THE DRAWINGS

Example embodiments will be more clearly understood from the following detailed description taken in conjunction with the accompanying drawings. FIGS. 1-2G represent non-limiting, example embodiments as described herein.

FIG. 1 is a diagram of an embedded DRAM with a capacitor under bit line structure according to a conventional art; and

FIGS. 2A to 2G are diagrams illustrating a method for fabricating an embedded DRAM with a capacitor under bit line structure according to example embodiments.

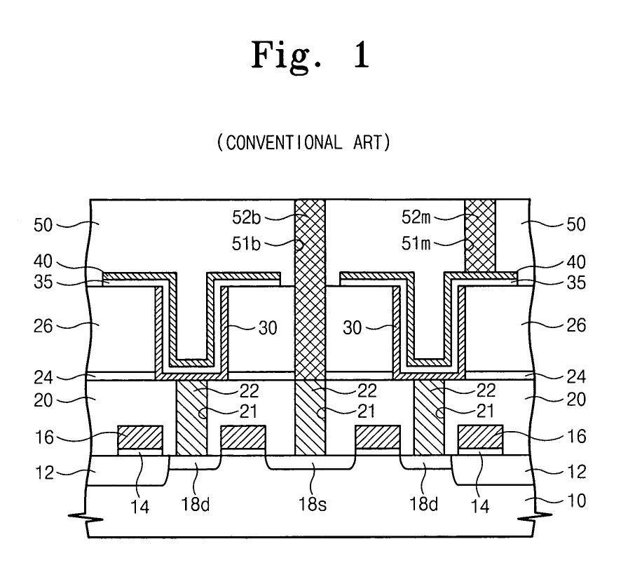

### DETAILED DESCRIPTION OF EXAMPLE EMBODIMENTS

Reference will now be made in detail to the example embodiments, examples of which are illustrated in the accompanying drawings. However, example embodiments are not limited to the embodiments illustrated herein after, and the example embodiments herein are rather introduced to provide easy and complete understanding of the scope and spirit of example embodiments. In the drawings, the thicknesses of layers and regions are exaggerated for clarity. It will also be understood that when a layer is referred to as being “on” another layer or substrate, it may be directly on the other layer or substrate, or intervening layers may also be present. Like reference numerals in the drawings denote like elements, and thus their detailed description will be omitted for conciseness.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” may encompass both an orientation of above and below. The device may be otherwise oriented (rotated 90° or at other orientations) and the spatially relative descriptors used herein interpreted accordingly.

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements and/or components, but do not preclude the presence or addition of one or more other features, integers, steps, operations, elements, components and/or groups thereof.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

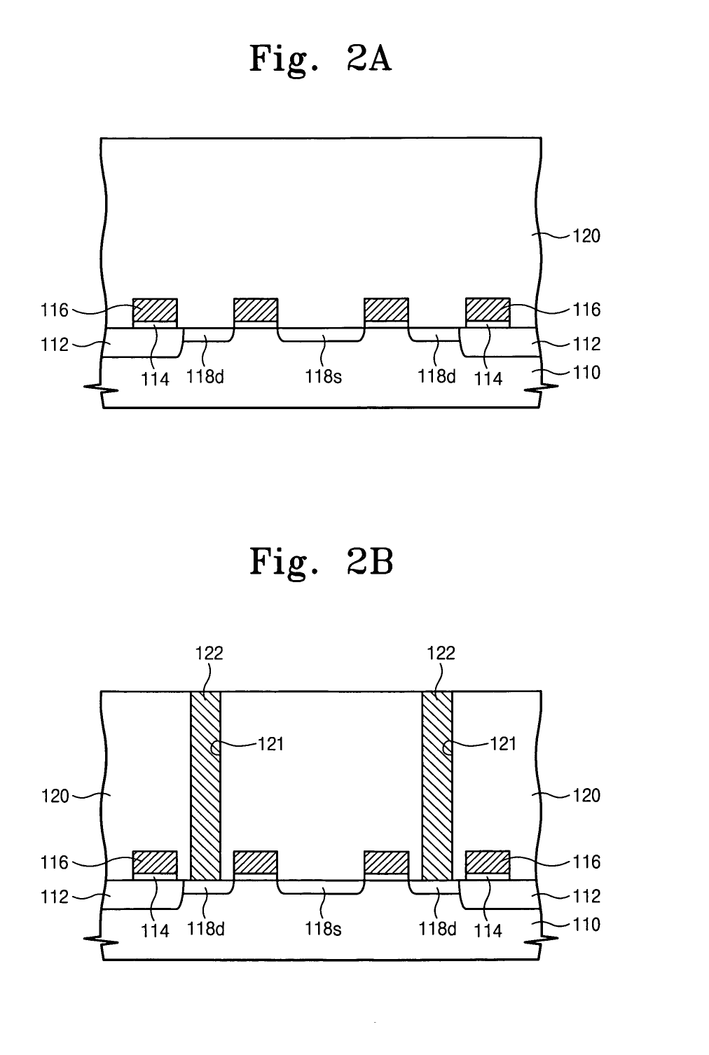

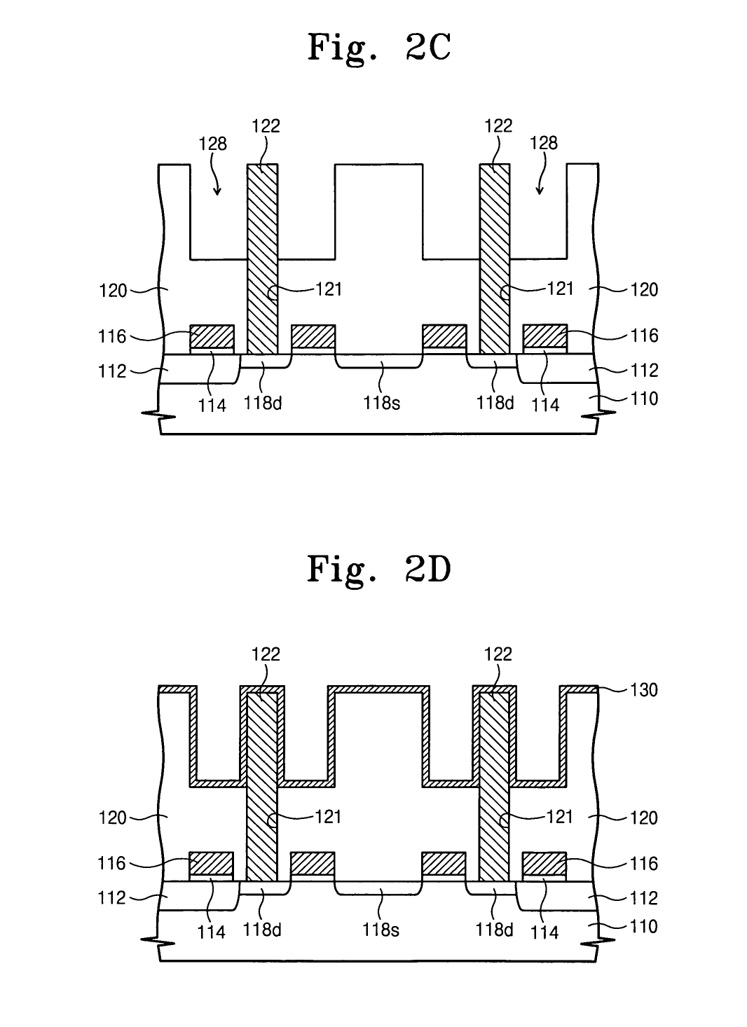

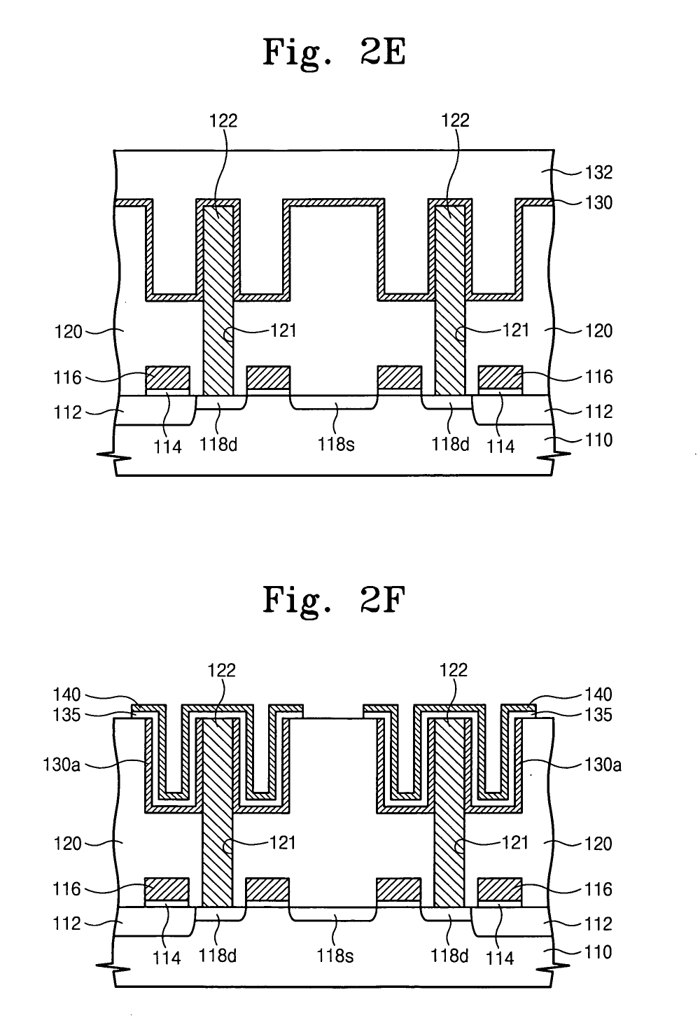

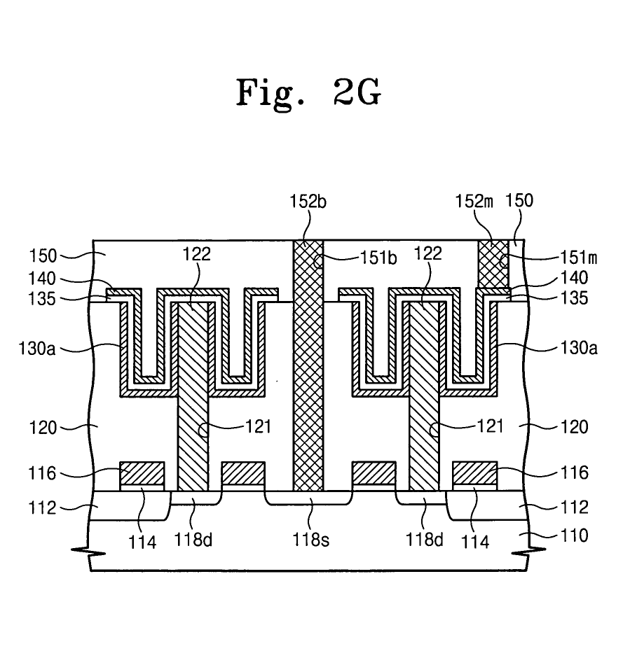

FIGS. 2A to 2G are diagrams illustrating a method for fabricating an embedded DRAM with a capacitor under bit line structure according to example embodiments. Referring to FIG. 2A, a device isolation layer 112 may be formed on a semiconductor substrate 110 by using a conventional device isolation process. A gate oxide layer 114, a gate electrode 116, and impurity regions (source/drain regions 118s/118d) may be formed on the semiconductor substrate 110 by performing a MOS transistor manufacturing process. The gate oxide layer 114 may be a thermal oxide layer. The gate electrode 116 may be formed of polysilicon. The impurity regions 118s and 118d may be formed by using an ion implantation process.

An interlayer insulation layer 120 may be formed to cover an entire surface of the semiconductor substrate 110 having the MOS transistor. The interlayer insulation layer 120 may be a silicon oxide layer deposited by using a Chemical Vapor Deposition (CVD) process. The interlayer insulation layer 120 may be a TetraEthly OrthoSilicate (TEOS) layer deposited by using a Plasma Enhanced CVD (PE-CVD) process. The interlayer insulation layer 120 may be formed at a thickness of about 15,000 Å to about 20,000 Å. The interlayer insulation layer 120 may be a bottom interlayer insulation layer and a top interlayer insulation layer having an etch stop layer therebetween. The etch stop layer may be a silicon nitride layer and/or a silicon oxide nitride layer, which may be deposited by using a PE-CVD process.

Referring to FIG. 2B, a photolithography process may be performed to etch the interlayer insulation layer 120, thereby exposing a predetermined or given region of the drain region 118d via a contact hole 121. A contact plug 122 may be formed to fill the contact hole 121. The contact plug 122 may be formed of tungsten by using a Pulsed Nucleation Layer (PNL) formation process. Before the forming of the contact plug 122, a barrier metal layer (not shown) may be formed to reduce or prevent diffusion at the interface between the contact plug 122 and the interlayer insulation layer 120 contacting each other. The barrier metal layer may be a double layer including titanium and titanium nitride.

Referring to FIG. 2C, after forming a photoresist pattern (not shown) on the interlayer insulation layer 120, a recess 128 exposing a upper portion of the contact plug 122 may be formed by using the photoresist pattern as a mask to etch the interlayer insulation layer 120. The recess 128 may be formed to a height of about 9,000 Å. When etching the interlayer insulating layer 120 to form the recess 128, the contact plug 122 may remain on a center of the recess without any loss because of its selectivity with respect to a silicon oxide. The top of the contact plug 122 may have a height almost identical to that of the top of the interlayer insulation layer 120. As described before, when the interlayer insulation layer 120 is a bottom interlayer insulation layer and a top interlayer insulation layer having an etch stop layer therebetween, the height of the recess 128 may be easily adjusted by the etch stop layer. The height of the recess 128 may be formed at a predetermined or given height. Referring to FIG. 2D, a bottom conductive layer 130 may be formed on a profile of the interlayer insulation layer 120 including the contact plug 122 that protrudes from the center of the recess 128. The bottom conductive layer 130 may be formed of a titanium nitride deposited by using a CVD process. The bottom conductive layer 130 may be formed of a thickness of about 200 Å.

Referring to FIG. 2E, a sacrificial insulation layer 132 may be formed to cover the bottom conductive layer 130 formed on the recess 128. The sacrificial insulation layer 132 may be formed of a photoresist. After etching the entire surface of the sacrificial insulation layer 132 and the bottom conductive layer 130 until the surface of the interlayer insulation layer 120 is exposed, the sacrificial insulation layer 132 remaining on the recess 128 may be removed to form a bottom electrode 130a on a profile inside the recess 128. The sacrificial insulation layer 132 remaining on the recess 128 may be removed by using an ashing process. The etching of the entire surface of the sacrificial insulation layer 132 and the bottom conductive layer 130 may be performed by using a Chemical Mechanical Polishing (CMP) process. After depositing the bottom conductive layer 130, dielectric material, and the top conductive layer, a bottom electrode 130a may be formed by patterning the result.

Referring to FIG. 2F, the dielectric material and the top conductive layer that cover the interlayer insulation layer 120 having the bottom electrode 130a may be deposited and patterned to form a dielectric layer 135 and a top electrode 140. The dielectric material may be formed of a double layer including aluminum oxide and hafnium oxide. The aluminum oxide and the hafnium oxide may be deposited by using a CVD process to be formed to thicknesses of about 25 Å and about 40 Å, respectively. The top conductive layer may be formed of a double layer-deposited titanium nitride by using a CVD process and a Self-Ionized Plasma Physical Vapor Deposition (SIP-PVD) process. The top conductive layer may be formed of a thickness of about 1,000 Å.

Referring to FIG. 2G, a planarizing insulation layer 150 may be formed to cover the semiconductor substrate 110 having the top electrode 140. The planarizing insulation layer 150 may be formed of a silicon oxide deposited by using a CVD process. The planarizing insulation layer 150 may be a TEOS layer deposited by using a PE-CVD process. The planarizing insulation layer 150 and the interlayer insulation layer 120 may be etched to form a bit line contact hole 151b exposing a predetermined or given region of the source region 118s, and a metal line contact hole 151m exposing a predetermined or given region of the top electrode 140. The bit line contact hole 151b and the metal line contact hole 151m may be filled to form a bit line contact plug 152b and a metal line contact plug 152m. For example, the bit line contact plug 152b and the metal line contact plug 152m may be formed of tungsten deposited by using a PNL formation process.

Before forming the bit line contact plug 152b and the metal line contact plug 152m, a barrier metal layer (not shown) may be formed to reduce or prevent diffusion during a thermal treatment process at the interface between the bit line contact plug 152b and the metal line contact plug 152m that contact each other and the interlayer insulation layer 120 and the sacrificial insulation layer 132 that contact each other. According to example embodiments, when fabricating a cylindrical capacitor under bit line structure, a bottom electrode having a larger surface area may be formed in the cylindrical capacitor. Example embodiments may provide a capacitor of the semiconductor device with an improved capacitance, and a method for fabricating the same.

As described above, example embodiments provide the capacitor of the semiconductor device with the improved capacitance by simply changing a processing structure without additional photolithography, and a method for fabricating the same. It will be apparent to those skilled in the art that various modifications and variations may be made in example embodiments. Thus, it is intended that example embodiments provide the modifications and variations of example embodiments provided they come within the scope of the appended claims and their equivalents.

What is claimed is:

1. A method comprising:
forming an interlayer insulation layer on a semiconductor substrate;
patterning the interlayer insulation layer to form a contact hole exposing a region of the semiconductor substrate; and
forming a contact plug by filling the contact hole, wherein a top of the contact plug has a height identical to that of the interlayer insulation layer.

2. The method of claim 1, further comprising:
forming a recess on the interlayer insulation layer, the recess exposing a portion of the contact plug;
forming a bottom electrode on an inner profile of the recess including sides of the contact plug; and
depositing a dielectric layer and a top electrode on a profile of the semiconductor substrate including the bottom electrode to form a capacitor.

3. The method of claim 1, wherein forming the interlayer insulation layer includes forming the interlayer insulation layer of a silicon oxide.

4. The method of claim 1, further comprising:
forming an etch stop layer in a middle of the interlayer insulation layer, wherein the interlayer insulation layer formed on the etch stop layer has a thickness that becomes a depth of the recess.

5. The method of claim 4, wherein forming the etch stop layer includes forming the etch stop layer of one of a silicon oxide nitride layer and a silicon nitride layer.

6. The method of claim 1, wherein forming the contact plug includes forming the contact plug of tungsten.

7. The method of claim 2, wherein forming the recess includes performing an anisotropic dry etching process.

8. The method of claim 2, wherein forming the bottom electrode includes:
depositing a bottom conductive layer on a profile of the recess;
forming a sacrificial insulation layer that covers the semiconductor substrate including the bottom conductive layer and the recess;
etching an entire surface of the sacrificial insulation layer and the bottom conductive layer to expose a surface of the interlayer insulation layer; and
removing the sacrificial insulation layer remaining in the recess by an ashing process.

9. The method of claim 8, wherein depositing the bottom conductive layer includes depositing titanium nitride.

10. The method of claim 8, wherein forming the sacrificial insulation layer includes forming a photoresist.

11. The method of claim 8, wherein etching the entire surface of the sacrificial insulation layer and the bottom conductive layer includes performing a CMP (chemical mechanical polishing) process.

12. The method of claim 2, wherein depositing the dielectric layer includes depositing a double layer including aluminum oxide and hafnium oxide.

13. The method of claim 2, wherein depositing the top electrode includes depositing the top electrode formed of a titanium nitride.

14. A device comprising:
a gate electrode on a semiconductor substrate;
an interlayer insulating layer covering an entire surface of the semiconductor substrate including the gate electrode and having a recess; and
a contact plug connected to a region of the semiconductor substrate and protruding from a center of the recess, wherein a top of the contact plug has a height identical to that of the interlayer insulation layer.

15. The device of claim 14, further comprising:
a bottom electrode on an inner profile of the recess including sides of the contact plug; and
a dielectric layer and a top electrode on a profile of the semiconductor substrate including the bottom electrode.

16. The device of claim 14, wherein the interlayer insulation layer is a silicon oxide layer.

17. The device of claim 16, further comprising:
an etch stop layer in a middle of the interlayer insulation layer.

18. The device of claim 17, wherein the etch stop layer is one of a silicon oxide nitride layer and a silicon nitride layer.

19. The device of claim 14, wherein the contact plug is formed of tungsten.

20. The device of claim 15, wherein the bottom electrode is formed of a titanium nitride layer.

21. The device of claim 15, wherein the dielectric layer is a double layer including aluminum oxide and hafnium oxide.

22. The device of claim 15, wherein the top electrode is formed of a titanium nitride layer.
